(19) United States
(12) Patent Application Publication
(10) Pub. No.: US 2025/0233016 A1
(43) Pub. Date: Jul. 17, 2025

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: JHENG-HONG JIANG, HSINCHU (TW); SHING-HUANG WU, HSINCHU CITY (TW); CHIA-WEI LIU, HSINCHU COUNTY (TW)

(21) Appl. No.: 18/409,829

(22) Filed: Jan. 11, 2024

(51) Int. Cl. H01L 21/768; H01L 21/311; H01L 23/522

(52) U.S. Cl. CPC H01L 21/76832; H01L 21/31116; H01L 21/76807; H01L 21/76877; H01L 23/5226

(57) ABSTRACT

An integrated circuit device and a method of manufacturing the same are provided. The method includes steps of: forming a semiconductor device on a substrate; forming a first interconnect structure and a dielectric layer over the semiconductor device; and forming a second interconnect structure over the first interconnect structure, wherein the formation of the second interconnect structure includes: forming an insulating film over the first interconnect structure; depositing an etch stop layer over the insulating film, wherein the etch stop layer and the insulating film include different materials; depositing an isolation layer over the etch stop layer; performing a first etching operation to form a via penetrating the isolation layer and exposing the etch stop layer; and performing a second etching operation to extend the via downward to penetrate the etch stop layer and the insulating film and expose a portion of the first interconnect structure.

### BACKGROUND

In an integrated circuit, a very large number of circuit elements, such as transistors, capacitors, resistors and the like, are formed in or on an appropriate substrate. Due to the large number of circuit elements and a required complex layout of advanced integrated circuits, electrical connections of individual circuit elements are generally not established within a same level on which the circuit elements are manufactured. Typically, such electrical connections are formed in one or more additional metallization layers. These metallization layers generally include metal-containing lines, providing inner-level electrical connection, and also include a plurality of inter-level connections, also referred to as vias, that are formed of an appropriate metal. Thus, the vias provide the electrical connection between two neighboring stacked metallization layers.

Due to continuous reduction of feature sizes of circuit elements in modern integrated circuits, a number of circuit elements for a given chip area also increases, thereby requiring ever-greater increases in numbers of electrical connections to provide desired circuit functionality.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a flowchart of a method of manufacturing an integrated circuit device, in accordance with some embodiments of the present disclosure.

FIGS. 2A to 2N are cross-sectional views of intermediate stages of a method of manufacturing an integrated circuit device, in accordance with some embodiments of the present disclosure.

FIG. 3 is a flowchart of a method of manufacturing an integrated circuit device, in accordance with some embodiments of the present disclosure.

FIGS. 4A to 4P are cross-sectional views of intermediate stages of a method of manufacturing an integrated circuit device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

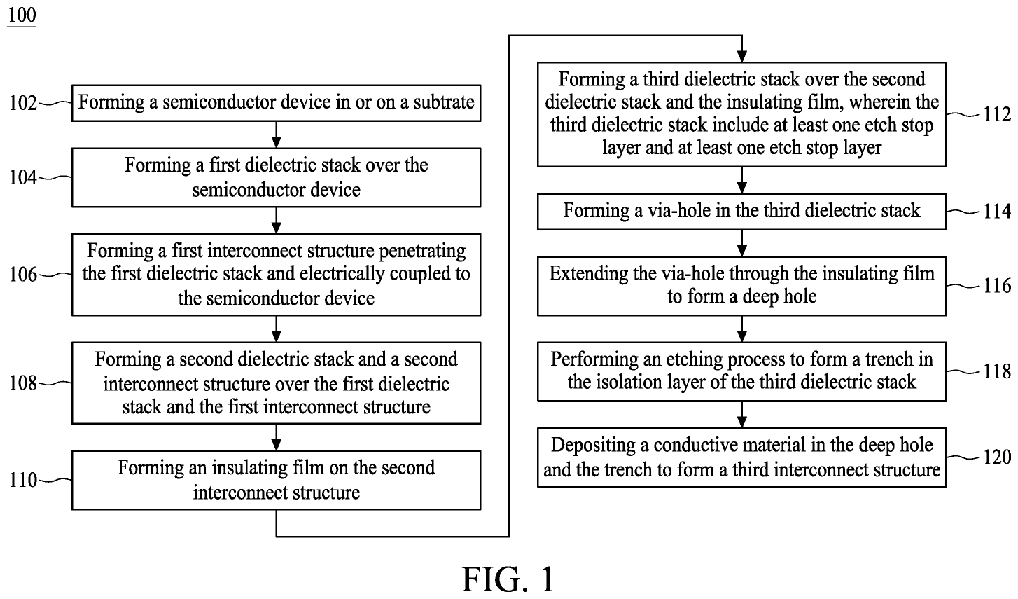

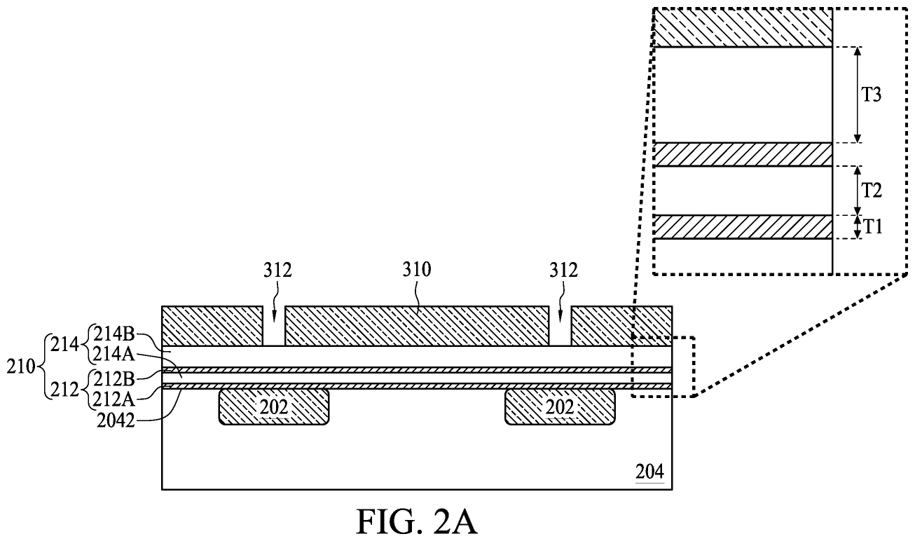

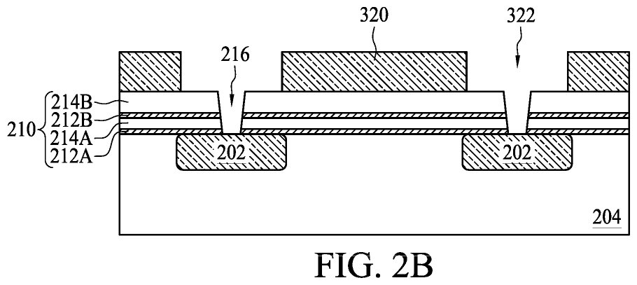

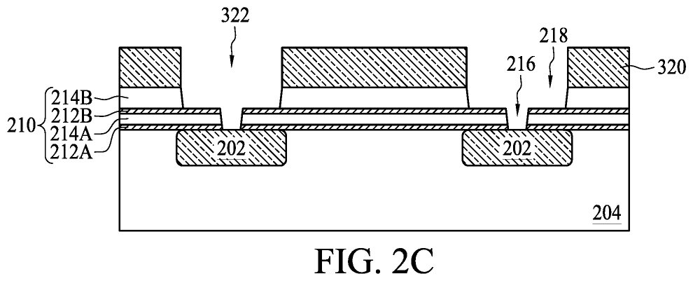

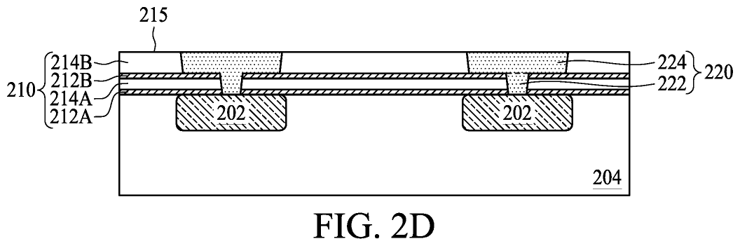

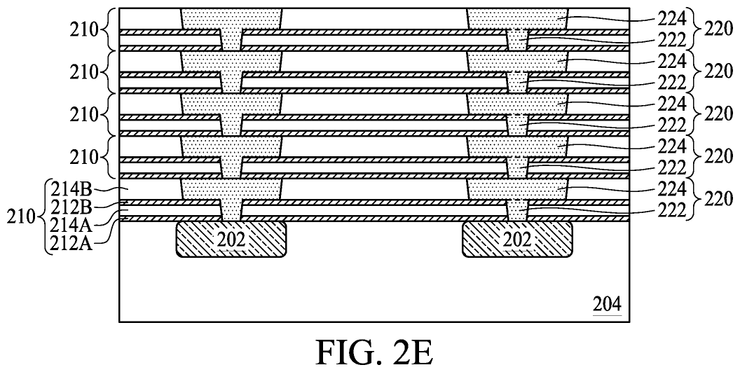

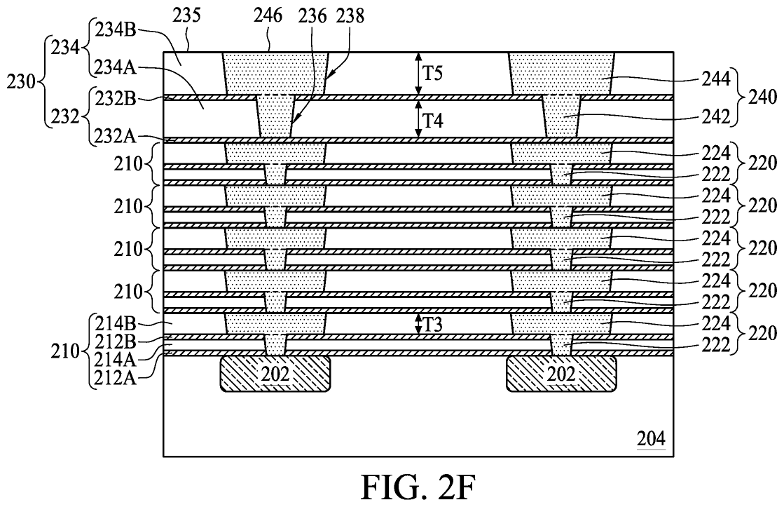

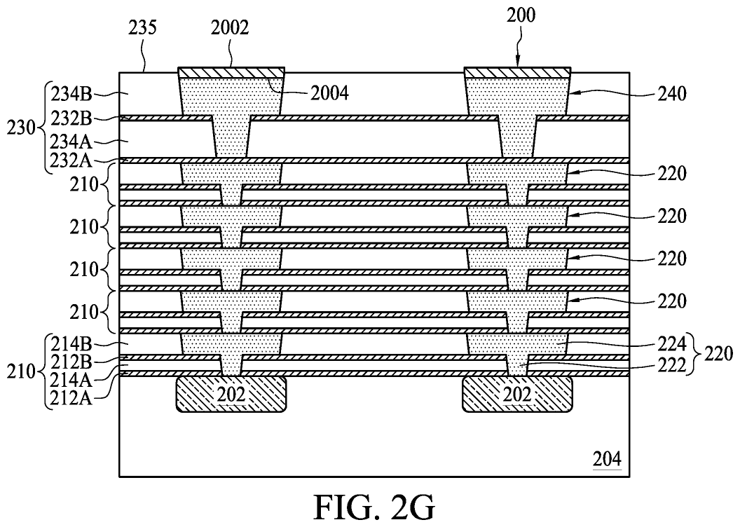

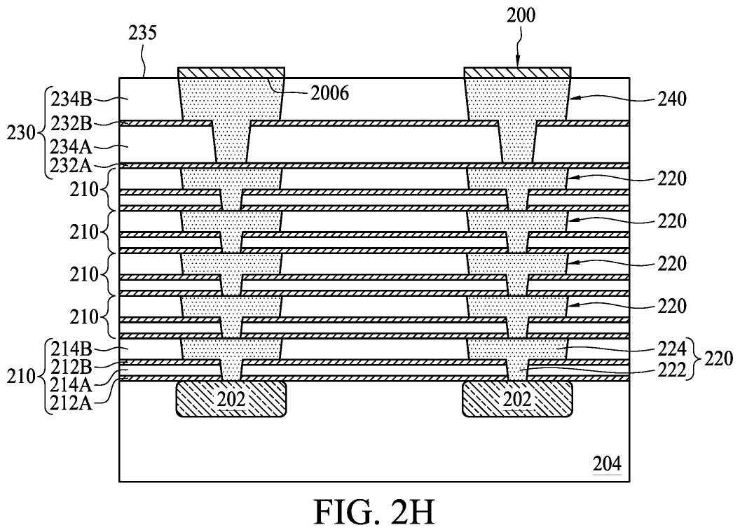

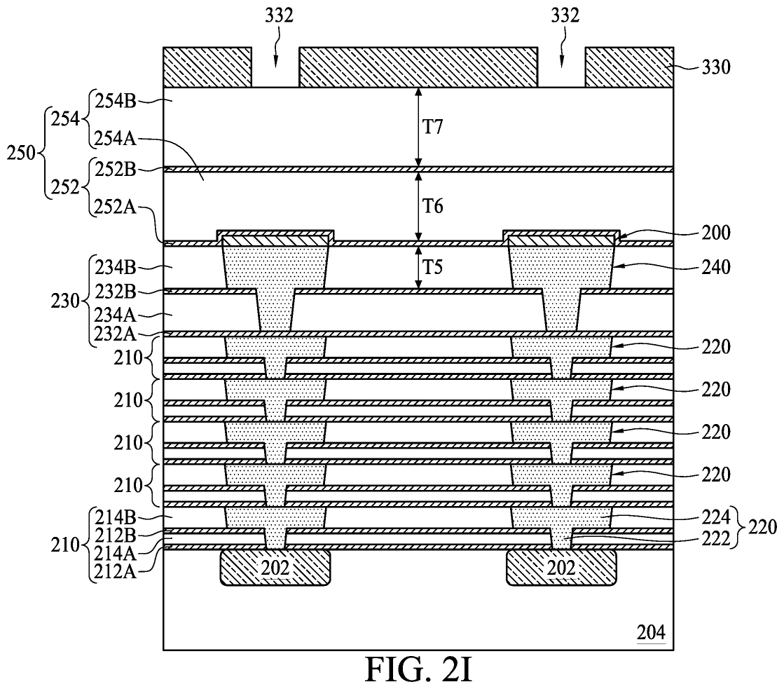

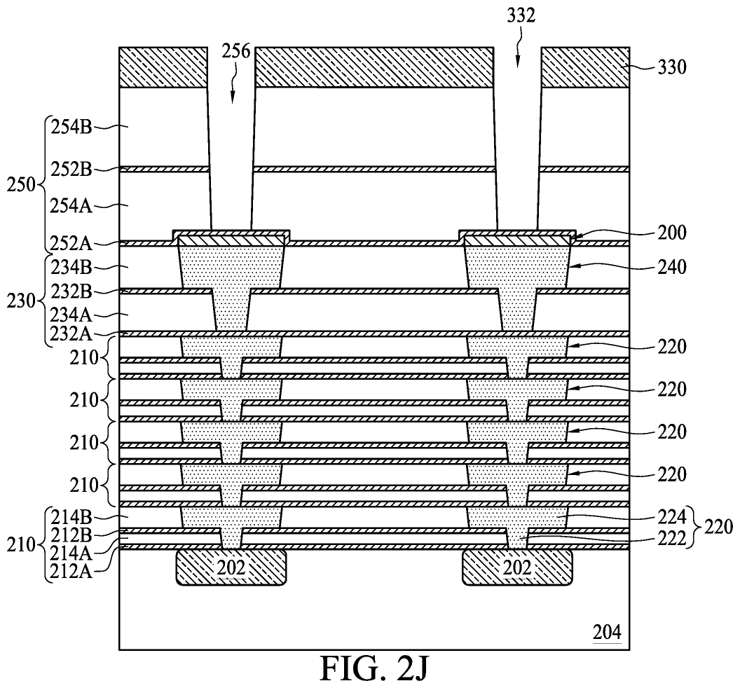

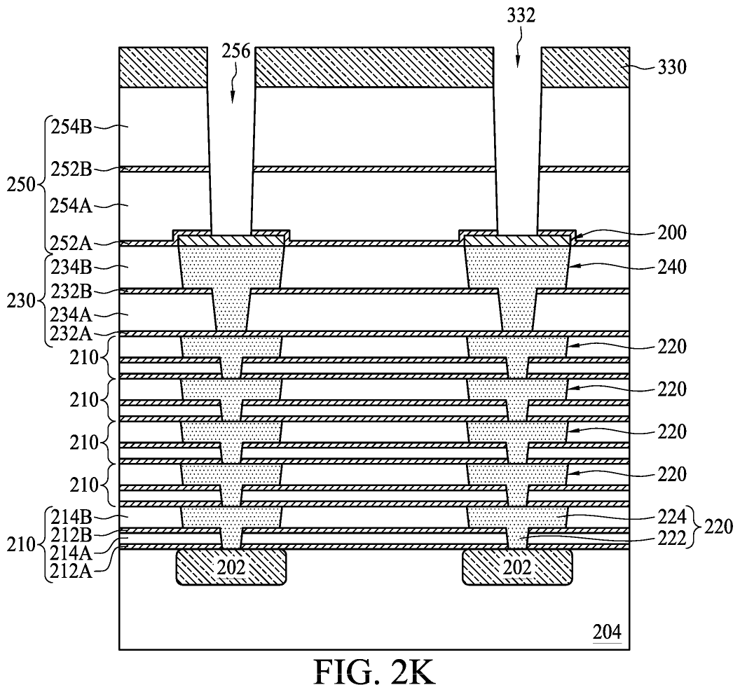

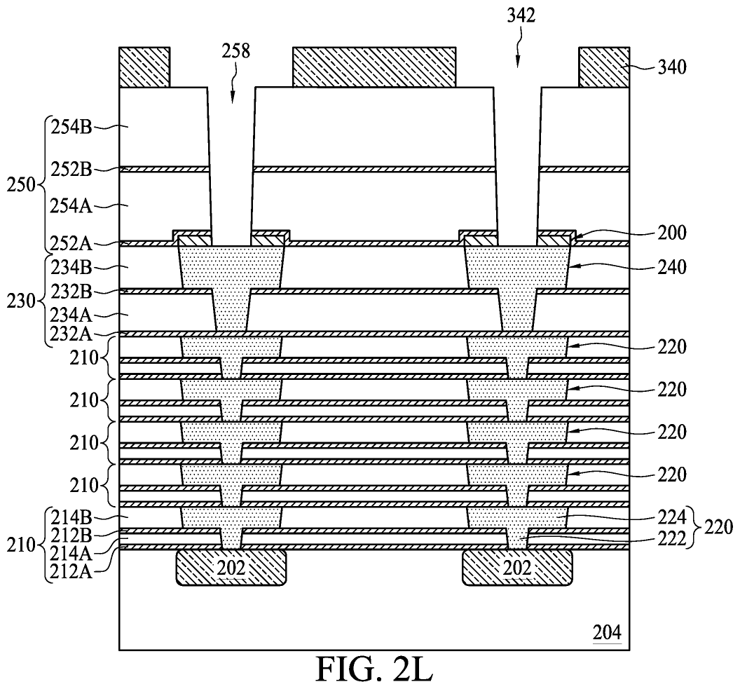

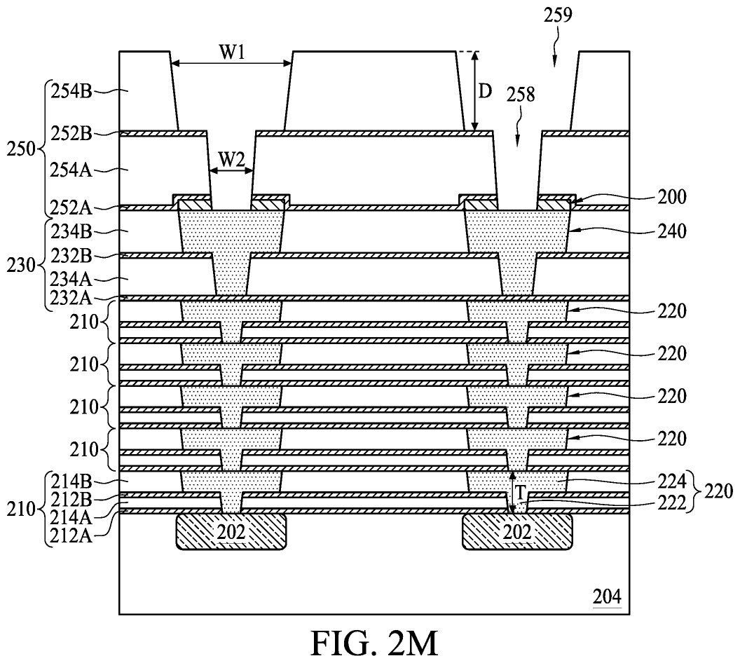

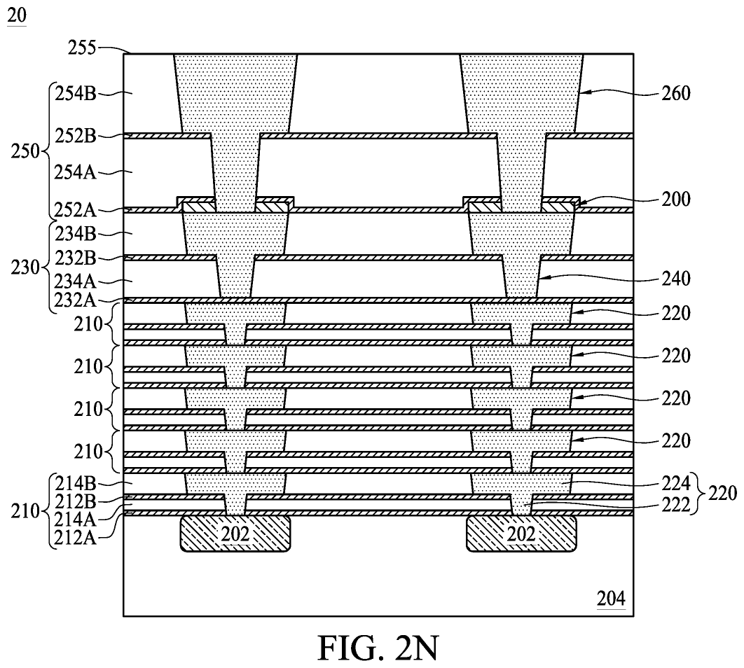

FIG. 1 is a flowchart of a method 100 of manufacturing an integrated circuit device 20, in accordance with some embodiments of the present disclosure. FIGS. 2A to 2N are cross-sectional views of intermediate stages of the method 100 of manufacturing the integrated circuit device 20, in accordance with some embodiments of the present disclosure. In the following discussion, the manufacture stages shown in FIGS. 2A to 2N are discussed in reference to the process steps shown in FIG. 1. It should be understood that additional steps can be provided before, during, and after the steps shown in FIG. 1, and that some of the steps described below can be replaced or eliminated for additional embodiments of the method 100. The order of the steps may be changed.

Referring to FIG. 2A, one or more semiconductor devices 202 are formed in or on a substrate 204 according to step 102 of FIG. 1. The substrate 204 may be a semiconductor substrate. In some embodiments, the substrate 204 may be a silicon substrate. Alternatively, the substrate 204 may comprise another elementary semiconductor, such as germanium; a compound semiconductor including silicon carbide; an alloy semiconductor including silicon germanium; or a combination thereof.

The semiconductor devices 202 may be formed during a front-end-of-line (FEOL) process. The semiconductor devices 202 may include, without limitation, active devices such as transistors and/or passive devices such as diodes, resistors or capacitors. Various processes are performed to form the semiconductor devices 202, such as deposition, etching, implantation, photolithography, annealing, and/or other applicable processes.

Still referring to FIG. 2A, a first dielectric stack 210 is formed over the semiconductor devices 202 and the substrate 204 according to step 104 of FIG. 1. The first dielectric stack 210 includes a series of first etch stop layers 212 and first isolation layers 214 stacked alternatingly arranged with each other. For example, the first dielectric stack 210 may include two first etch stop layers 212A and 212B interleaved with two first isolation layers 214A and 214B. As shown in FIG. 2A, the first etch stop layer 212A is in contact with an upper surface 2042 of the substrate 204, and the first isolation layer 214A, the first etch stop layer 212B, and the first isolation layer 214B are sequentially disposed on the first etch stop layer 212A. In some embodiments, the first etch stop layer 212A may have a thickness T1, the first isolation layer 214A may have a thickness T2 greater than the thickness T1, and the first isolation layer 214B may have a thickness T3 greater than the thickness T2. For example, the thickness T3 of the first isolation layer 214B is in a range from about 500 angstroms to about 10 micrometers (100 k angstroms).

The first etch stop layers 212A and 212B include a first material different from a second material used to form the first isolation layers 214A and 214B. Specifically, the first material may have a high etching selectivity to the second material, and hence the first etch stop layers 212A and 212B may be used to stop an etching of the first isolation layers 214A and 214B, respectively. Examples of the first material include, but are not limited to, silicon nitride, silicon carbide, undoped silicon glass (USG), phosphosilicate glass (PSG), fluorinated silica glass (FSG), black diamond, low dielectric constant (low-k) materials, extreme low dielectric constant (ELK) materials, or the like. Examples of the second material include, but are not limited to, silicon oxide (SiO_{X}) such as silicon dioxide (SiO₂), silicon nitride, undoped silicon glass (USG), phosphosilicate glass (PSG), fluorinated silica glass (FSG), black diamond, other suitable low dielectric constant or extreme low dielectric constant (ELK) materials, and/or combinations thereof. The first etch stop layers 212A and 212B and the first isolation layers 214A and 214B may be formed by any suitable process, with suitability depending on the material used. Examples of processes for depositing the first etch stop layers 212A and 212B and the first isolation layers 214A and 214B include spin-coating, chemical vapor deposition (CVD), physical vapor deposition (PVD), atomic layer deposition (ALD), and other applicable processes. In some embodiments, the first isolation layers 214A and/or 214B may be planarized, such as by a chemical mechanical polishing (CMP) operation, to have a planar top surface.

After the dielectric stack 210 is completely formed, a first patterned mask layer 310 is formed over the first isolation layer 214B, wherein the first patterned mask layer 310 includes a plurality of first openings 312. Portions of the first isolation layer 214B are exposed through the first openings 312. In some embodiments, although two first openings 312 are illustrated in FIG. 2A, such number of the first openings 312 in the first patterned mask layer 310 is not intended to be limiting. For example, the first patterned mask layer 310 may include only one first opening 312. A shape of the first openings 312 may be adjusted as required. In some embodiments, the first patterned mask layer 310 may include a photoresist, and the first openings 312 are formed by a lithography operation.

Referring to FIGS. 2B to 2D, a first interconnect structure 220 is formed over the semiconductor devices 202 according to step 106 of FIG. 1. After the first patterned mask layer 310 is formed, a first etching operation is performed to etch the first dielectric stack 210 through the first openings 312, so that one or more first via-holes 216 are formed in the first dielectric stack 210. As shown in FIG. 2B, the first dielectric stack 210 is etched until one or more portions of the semiconductor devices 202 are exposed. In some embodiments, the first dielectric stack 210 is anisotropically etched by a plasma-based etching process, such as a reactive ion etching (RIE) process, or the like. The first patterned mask layer 310 is used to limit a high-energy plasma etch to a desired pattern for the first via-holes 216.

After the first via-holes 216 are formed, the first patterned mask layer 310 is removed in an ashing and/or wet strip process, for example. Subsequently, a second patterned mask layer 320 is formed on the first dielectric stack 210 to cover portions of the first isolation layer 214B. The second patterned mask layer 320 includes one or more second openings 322 connected to the first via-holes 216.

In FIG. 2C, a second etching operation is performed to etch the first isolation layer 214B to form one or more first trenches 218 in the first isolation layer 214B. The second etching operation stops at the first etch stop layer 212B. In some embodiments, the first isolation layer 214B is etched by an anisotropic etching process such as an RIE process. In some embodiments, the first dielectric stack 210 is patterned using a dual damascene process, and the dual damascene process is, for example, a via-first-trench-last (VFTL) approach.

After the second etching operation is performed, the second patterned mask layer 320 is removed. Next, a conductive material is provided to fill the first via-holes 216 and the first trenches 218, as shown in FIG. 2D. In some embodiments, the conductive material is deposited and forms the first interconnect structure 220 to be electrically coupled to the semiconductor devices 202. Examples of the conductive material include, but are not limited to, tungsten (W), copper (Cu), aluminum (Al), cobalt (Co), nickel (Ni), an aluminum-copper alloy (AlCu), an aluminum-copper-silicon alloy, and the like. The conductive material may be formed or deposited by an electro-chemical plating process, a CVD process, a PVD process, an ALD process, or other applicable deposition operation. After the conductive material fills or is deposited in the first via-holes 216 and the first trenches 218, excess portions of the conductive material are removed to expose a top surface 215 of the first isolation layer 214B. The excess portions of the conductive material may be removed by a CMP operation.

In some embodiments, the first interconnect structure 220 may include one or more first conductive metals 224 surrounded by the first isolation layer 214B and a plurality of first vias 222 sandwiched between the first conductive metal(s) 224 and the semiconductor devices 202. The first vias 222 connect the semiconductor devices 202 to the first conductive metal(s) 224 and are surrounded by the first etch stop layers 212A and 212B and the first isolation layer 214A.

When the conductive material includes copper, the first interconnect structure 220 may further include a thin glue film (not shown) interposed between the first interconnect structure 220 and the semiconductor devices 202 and between the first interconnect structure 220 and the first dielectric stack 210 for preventing copper from diffusing into the first dielectric stack 210. The glue film may be made of tantalum nitride, although other materials, such as tantalum, titanium, titanium nitride, or the like, may also be used. The glue film is conformally deposited on the first isolation layer 214B and in the first via-holes 216 and the first trenches 218 prior to the deposition of the conductive material. After the deposition of the conductive material, the CMP operation is performed to remove the excess portions of the conductive material and an excess portion of the glue film from the top surface 215 of the first isolation layer 214B. The glue film may be deposited with a substantially uniform thickness using an acceptable deposition operation such as a CVD operation, a PVD operation, an ALD operation, or the like.

In some embodiments, additional first dielectric stacks 210 and first interconnect structures 220 are formed over the substrate 204 to be electrically coupled to the semiconductor devices 202. Referring to FIG. 2E, five layers of first interconnect structures 220 are shown over the semiconductor devices 202, but an actual number of the first interconnect structures 220 is not limited thereto.

Referring to FIG. 2F, a second dielectric stack 230 and a second interconnect structure 240 are formed over the first dielectric stacks 210 and the first interconnect structures 220 according to step 108 of FIG. 1. The second dielectric stack 230 includes a series of second etch stop layers 232 and second isolation layers 234 deposited alternatingly with the second etch stop layers 232. For example, the second dielectric stack 230 includes two second etch stop layers 232A and 232B and two second isolation layers 234A and 234B.

The second etch stop layers 232A and 232B may include the first material used to form the first etch stop layers 212A and 212B, and the second isolation layers 234A and 234B may include the second material used to form the first isolation layers 214A and 214B. The second etch stop layers 232A and 232B may be formed in a manner similar to that used to form the first etch stop layers 212A and 212B, and the second isolation layers 234A and 234B may be formed in a manner similar to that used to form the first isolation layers 214A and 214B. In some embodiments, the second isolation layer 234A may have a thickness T4 greater than the thickness T3 of the first isolation layer 214B, and the second isolation layer 234B may have a thickness T5 greater than the thickness T4 of the second isolation layer 234A. For example, the thickness T5 of the second isolation layer 234B is in a range from about 1500 angstroms to about 10 micrometers (100 k angstroms).

The formation of the second interconnect structure 240 may include a dual damascene process, which includes forming second via-holes 236 in the second dielectric stack 230 and second trenches 238 in the second isolation layer 234B, depositing the conductive material in the second via-holes 236 and the second trenches 238, and then performing a planarization such as a CMP operation to remove the excessive conductive material over the second isolation layer 234B. As such, a top surface 246 of the conductive material is level with an upper surface 235 of the second isolation layer 234B.

The second interconnect structure 240 includes a plurality of second vias 242 and one or more second conductive metal 244 connected to the second vias 242. The second vias 242 are sandwiched between the second conductive metal(s) 244 and a topmost first conductive metal 224 (i.e., the first conductive metal 224 farthest from the substrate 204). In FIG. 2F, the second conductive metal 244 is surrounded by the second isolation layer 234B, and the second vias 242 are surrounded by the second etch stop layers 232A and 232B and the second isolation layer 234A. In some embodiments, the second interconnect structure 240 may be formed of a same material as the first interconnect structure 220. The second interconnect structure 240 may be formed in a manner similar to that used to form the first interconnect structure 220.

The method 100 next proceeds to step 110, in which an insulating film 200 is formed, as shown in FIGS. 2G and 2H. The insulating film 200 includes a third material different from the first material of the first etch stop layer 212A and 212B. In some embodiments, the insulating film 200 includes metal oxide material, such as tungsten oxide (WₓO_{y}), copper oxide (CuₓO_{y}), aluminum oxide (AlₓO_{y}), aluminum copper dioxide (AlₓCu_{y}O_{z}), Nickel oxide (NiₓO_{y}), etc; although other dielectric material may also be used.

Referring to FIG. 2G, a surface region of the second conductive metal 244 is oxidized to form the insulating film 200. In such manner, the insulating film 200 includes an oxide of the material of the second conductive metal 244, and the insulating film 200 may have a pattern same as that of the second conductive metal 244 from a top-view perspective. The insulating film 200 includes an upper surface 2002 and a lower surface 2004 opposite to the upper surface 2002. The lower surface 2004 of the insulating film 200 and the upper surface 235 of the second isolation layer 234B are at different vertical levels, so a lower portion of the insulating film 200 is surrounded by the second isolation layer 234B. In some embodiments, the upper surface 235 of the second isolation layer 234B is between the lower surface 2004 of the insulating film 200 and the upper surface 2002 of the insulating film 200 in a cross-sectional view.

The oxidation of the second conductive metal 244 may include a baking operation in an oxygen atmosphere, or a plasma treatment including an O₂ plasma operation. In some embodiments, the oxidation is performed at a temperature greater than about 200° C.

Referring to FIG. 2H, in some embodiments, an alternative step of forming the insulating film 200, different from that shown in FIG. 2G, is performed. In such embodiments, the insulating film 200 is deposited on the second conductive metal 244. In such embodiments, the insulating film 200 may be formed of a material different from that of the second conductive metal 244. Additionally, the deposited insulating film 200 may have a lower surface 2006 flush with the upper surface 235 of the second isolation layer 234B. In some embodiments, the insulating film 200 may be formed by conformally depositing a dielectric layer on the second isolation layer 234B and the second conductive metal 244 and patterning the dielectric layer utilizing a mask layer having a pattern same as that of the second conductive metal 244.

Referring to FIG. 21, a third dielectric stack 250 is formed over the second dielectric stack 230 and the insulating film 200 according to step 112 of FIG. 1. The third dielectric stack 250 can include third etch stop layers 252 and third isolation layers 254 interleaved with the third etch stop layers 252. In some embodiments, there are two third etch stop layers 252A and 252B and two third isolation layers 254A and 254B in the third dielectric stack 250. In some embodiments, the third etch stop layer 252A is conformally deposited to cover the insulating film 200 and the second dielectric stack 230, and the third isolation layer 254A may have a substantially planar upper surface. In some embodiments, the third etch stop layer 252A is made of a material different from the insulating film 200. The third isolation layer 254B may have a thickness T7 in a range from 1500 angstroms to 100 k angstroms, and the third isolation layer 254A may have a thickness T6 greater than the thickness T5 of the second isolation layer 234B and less than the thickness T7 of the third isolation layer 254B. The third etch stop layers 252A and 252B may be formed in a manner similar to that used to form the first etch stop layers 212A and 212B, and may be formed of a material same as that used to form the first etch stop layers 212A and 212B. The third isolation layers 254A and 254B may be formed in a manner similar to that used to form the first isolation layers 214A and 214B, and may be formed of a material same as that used to form the first isolation layers 214A and 214B.

After the third dielectric stack 250 is formed, a third patterned mask layer 330 is formed on the third isolation layer 254B. The third patterned mask layer 330 is utilized to pattern the third dielectric stack 250, and includes one or more third openings 332 exposing one or more portions of the third isolation layer 254B.

Referring to FIGS. 2J to 2L, a third etching operation is performed to form one or more deep holes 258 extending through the third dielectric stack 250 and the insulating film 200. In some embodiments, the third etching operation can include multiple sub-etching steps with different etching recipes to sequentially etch through the third isolation layer 254B, the third etch stop layer 252B, the third isolation layer 254A, the third etch stop layer 252A, and the insulating film 200 while providing a desired etching rate and a desired etching selectivity.

Referring to FIG. 2J, portions of the third isolation layer 254B, the third etch stop layer 252B and the third isolation layer 254A not covered by the third patterned mask layer 330 are removed according to step 114 of FIG. 1. Hence, one or more third via-holes 256 are formed in the third dielectric stack 250. One or more portions of the third etch stop layer 252A are exposed through the third via-holes 256. Referring to FIG. 2K, the portions of the third etch stop layer 252A exposed through the third via-holes 256 are removed to extend the third via-holes 256 through the third etch stop layer 252A, thereby exposing one or more portions of the insulating film 200.

Referring to FIG. 2L, the insulating film 200 is etched to extend the third via-holes 256 through the insulating film 200 according to step 116 of FIG. 1. Accordingly, one or more deep holes 258 are formed. The third isolation layer 254B, the third etch stop layer 252B and the third isolation layer 254A are anisotropically etched by a plasma-based etching process, such as an RIE process, or the like.

The first via-holes 216 in the first dielectric stack 210 have a first aspect ratio, the second via-holes 236 in the second dielectric stack 230 have a second aspect ratio, and the third via-holes 256 in the third dielectric stack 250 have a third aspect ratio. The third aspect ratio is greater than not only the second aspect ratio but also the first aspect ratio because the third isolation layers 254A and 254B have the thicknesses greater than those of the second isolation layers 234A and 234B.

During the plasma-based etching process, reactive ions are created and are accelerated toward a surface to be treated in order to obtain a high directionality for providing a high-speed removing component using incident ions so that a substantially perpendicularly oriented removing component in combination with a chemical interaction of the reactive ions is achieved. In some embodiments, appropriate precursor materials are added to a plasma etching gas in order to form polymer compounds that significantly reduce a lateral etching rate, while substantially not affecting vertical etching progress of a corresponding etch front. Due to very complex conditions within the plasma etching gas, negative ions accumulate in the second interconnect structure 240, while positive charge accumulates in a lower portion of the third via-holes 256, thereby building up a vertical potential difference. Consequently, due to the accumulation of negative and positive charges, a localized potential difference is created in a vicinity of bottom of corresponding via-holes.

An effect of a significant potential difference may be pronounced in situations in which the dielectric material is thinned from above. Consequently, when the dielectric material reaches a certain thickness, the potential difference may be great enough to cause a dielectric breakdown of the remaining dielectric material, i.e., an uncontrollable discharge occurs, which is also referred to as an arcing event. In this case, a significant quantity of particles may be generated, for instance in a form of burned dielectric material, a burned conductive material, or the like, wherein such particles are scattered over a wide area of a semiconductor substrate, thereby increasing a range of contamination, which in turn may result in significant yield loss, or may at least cause deterioration of reliability of finished integrated circuit devices.

The plasma intensity depends on, e.g., the type of the etchants or gases, the pressure, the temperature and the radio frequency (RF) power used by an RF generator. In some embodiments, the third isolation layers 254A and 254B are etched with the RF power of higher than 1000 W. High RF power may cause more ions to accumulate on a lower portion of the third via-holes 256.

In some embodiments, an effective capacitance around the second interconnect structure 240 and the third via-holes 256 can be reduced by introduction of the insulating film 200. The insulating film 200 interposed between the second interconnect structure 240 and the third dielectric stack 250 may share a partial capacitance for reducing the equivalent capacitance between the second interconnect structure 240 and the surface to be etched in the third via-holes 256 during the plasma-etching process, thereby reducing the buildup of a non-desired high potential difference around the third via-holes 256. Consequently, due to the reduction of the high potential difference, a probability of the arcing everts may be significantly reduced or substantially eliminated.

After the third etching operation, a removal operation such as stripping or ozone ashing is performed to remove the third patterned mask layer 330. Subsequently, a fourth patterned mask layer 340 is formed on the portions of the third isolation layer 254B. The fourth patterned mask layer 340 includes one or more fourth openings 342 connected to the deep holes 258.

Referring to FIG. 2M, a fourth etching operation is performed to form one or more third trenches 259 in the third isolation layer 254B according to step 118 of FIG. 1. The fourth etching operation is performed to remove the material of the third isolation layer 254B selective to the material of the third etch stop layer 252B. In some embodiments, the third trenches 259 have a depth D greater than a thickness T of the first interconnect structure 220. In some embodiments, the third trenches 259 have a width W1 greater than a width W2 of the deep holes 258.

After the fourth etching operation is performed, the fourth patterned mask layer 340 is removed. Referring to FIG. 2N, a conductive material is provided to fill the deep holes 258 and the third trenches 259 according to step 120 of FIG. 1. In some embodiments, the conductive material is deposited and forms the third interconnect structure 260 physically and electrically connected to the second interconnect structure 240. After the conductive material fills or is deposited in the deep holes 258 and the third trenches 259, an excess portion of the conductive material is removed to expose a top surface 255 of the third isolation layer 254B. The excess portion of the conductive material may be removed by a CMP operation. Consequently, the integrated circuit device 20 is completely formed.

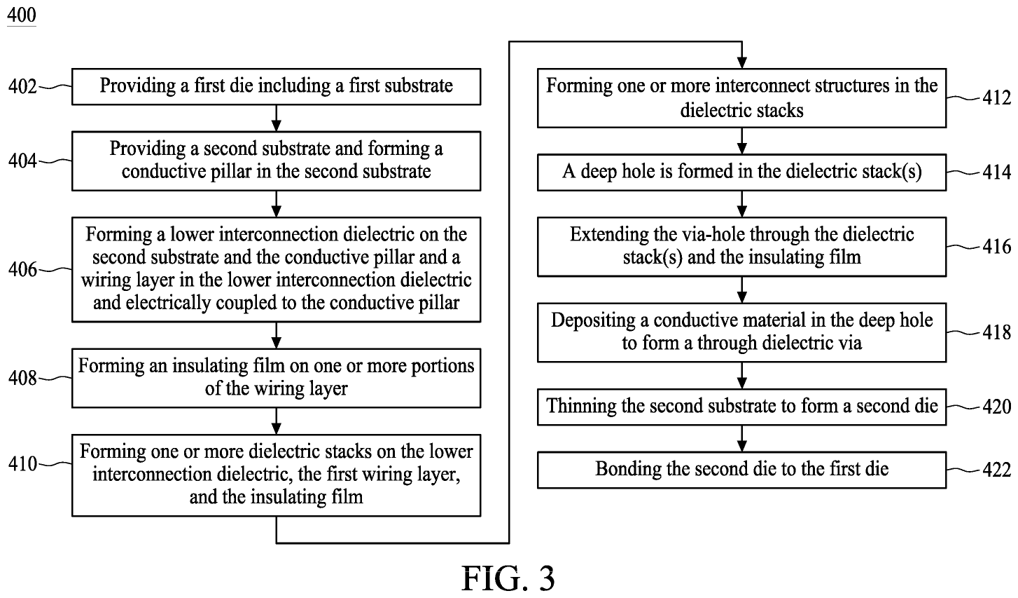

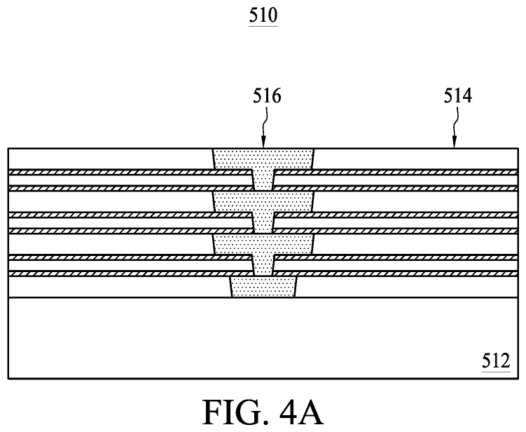

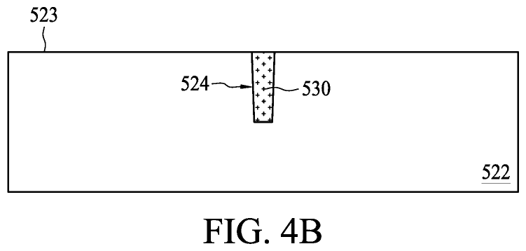

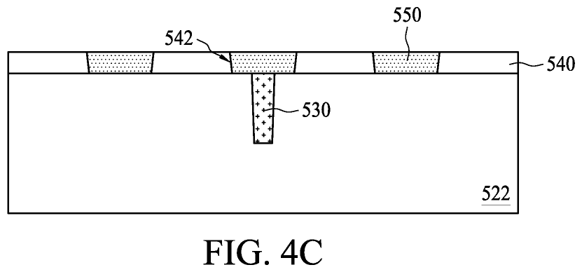

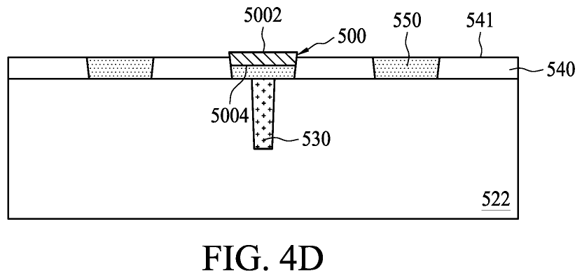

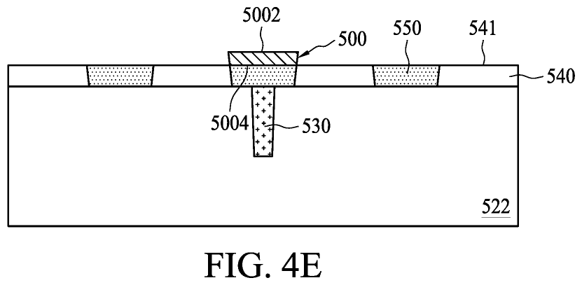

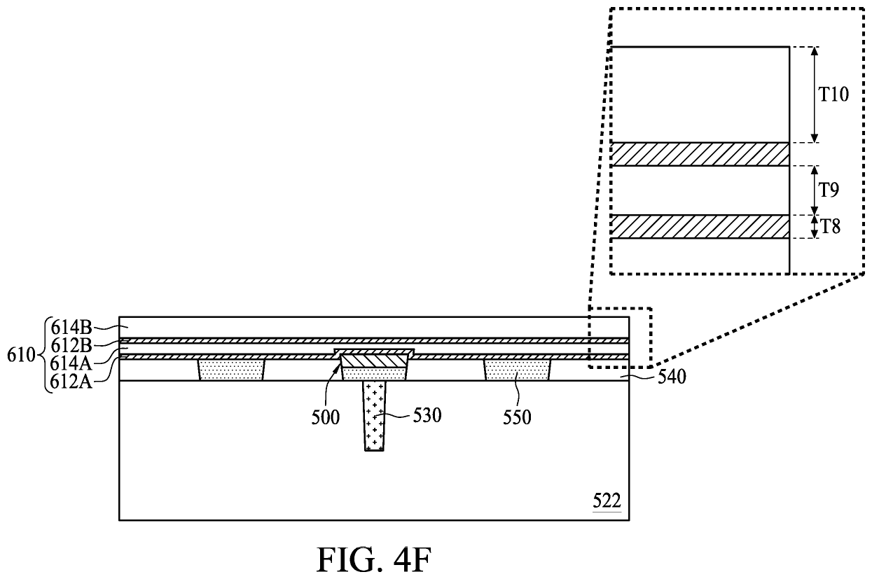

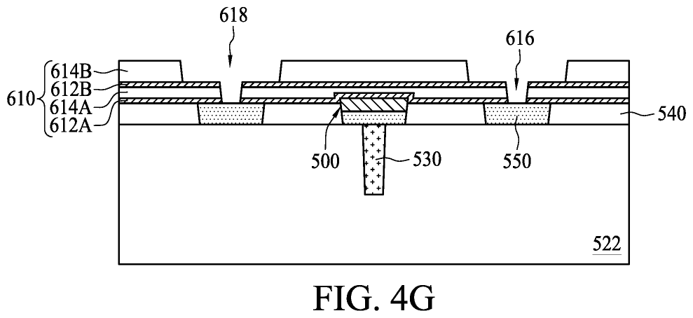

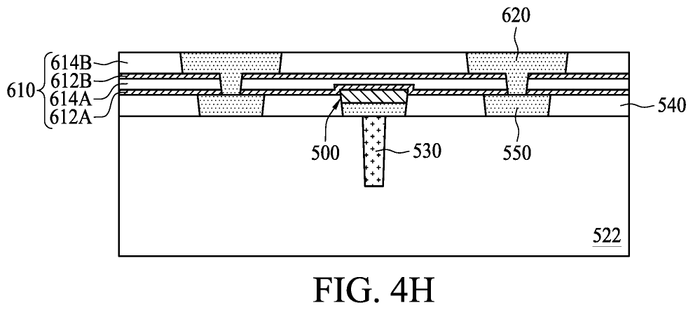

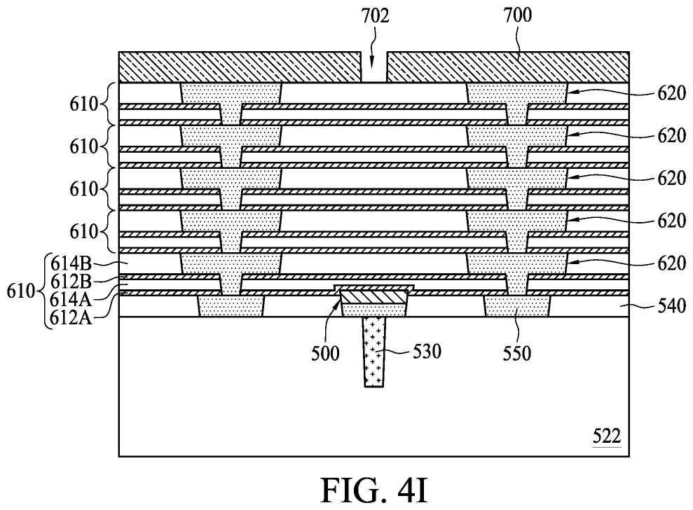

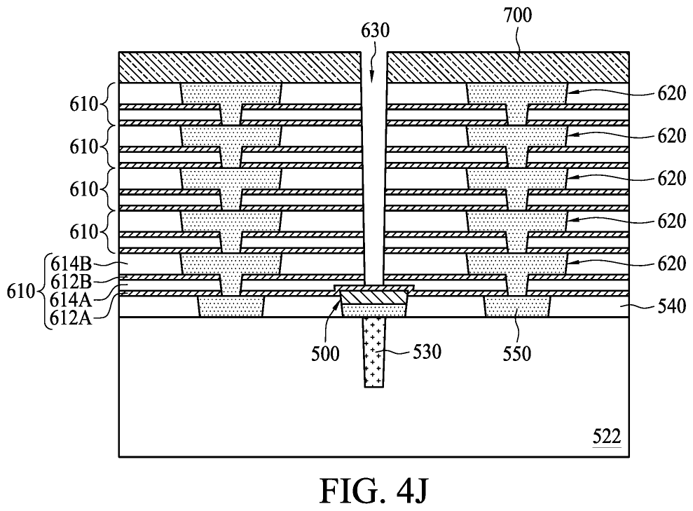

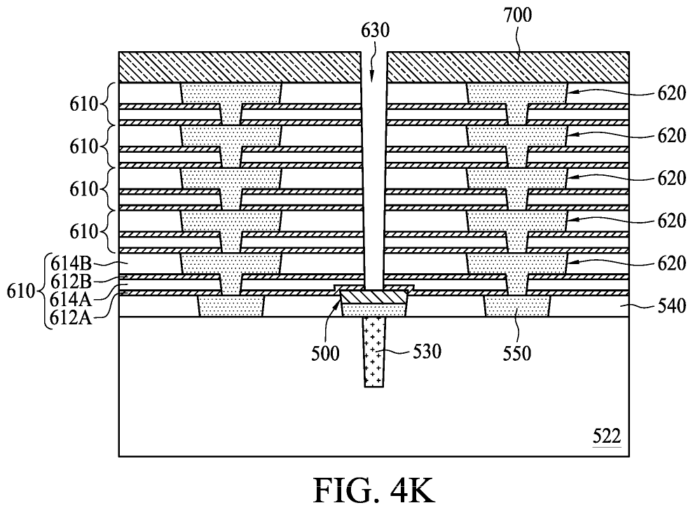

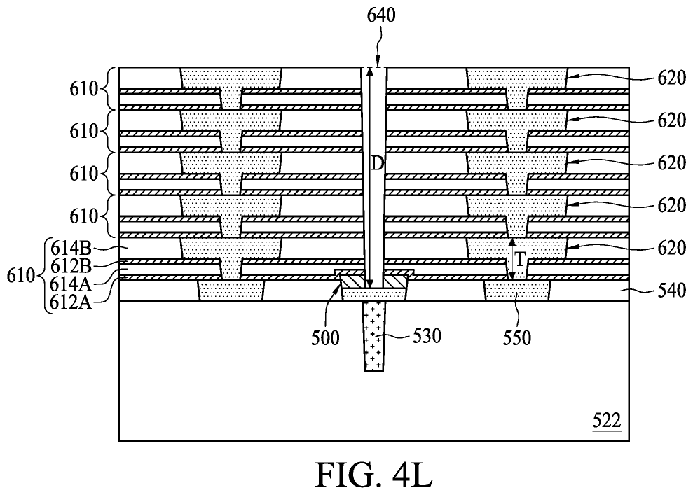

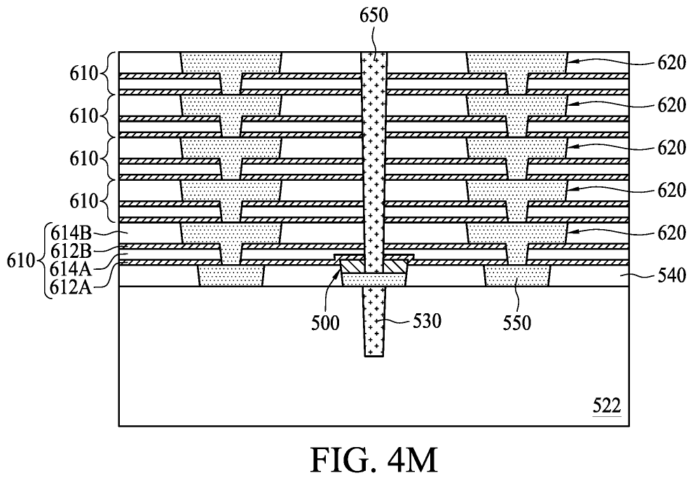

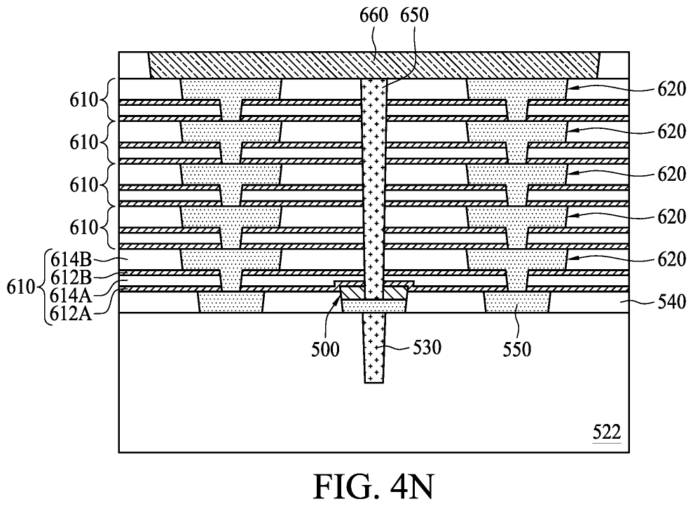

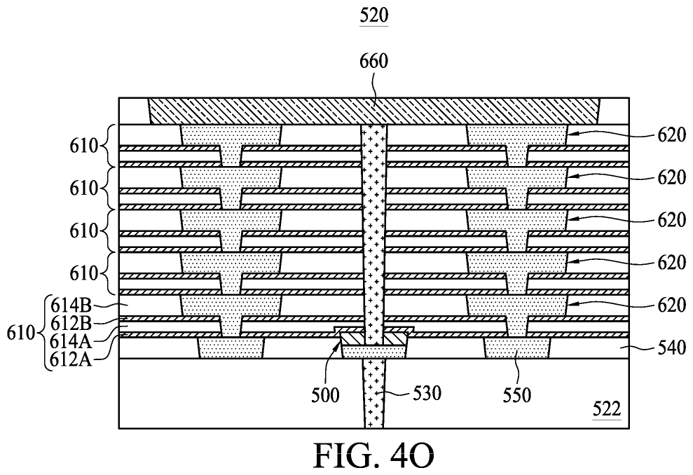

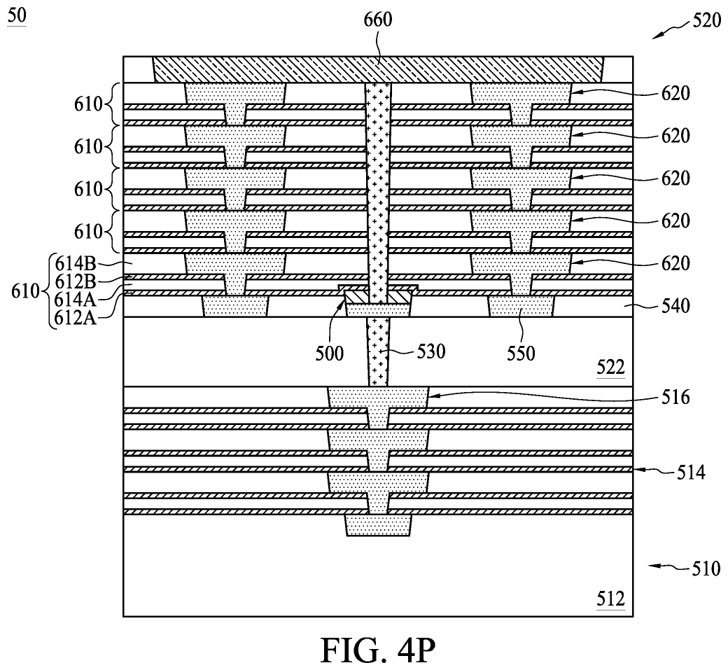

FIG. 3 is a flowchart of a method 400 of manufacturing an integrated circuit device 50, in accordance with some embodiments of the present disclosure. FIGS. 4A to 4P are cross-sectional views of intermediate stages of the method 400 of manufacturing the integrated circuit device 50, in accordance with some embodiments of the present disclosure. In the following discussion, the manufacture stages shown in FIGS. 4A to 4P are discussed in reference to the process steps shown in FIG. 3. It should be understood that additional steps can be provided before, during, and after the steps shown in FIG. 3, and some of the steps described below can be replaced or eliminated, for additional embodiments of the method 400. The order of the steps may be changed.

Referring to FIG. 4A, a first die 510 is provided according to step 402 of FIG. 3. The first die 510 includes a first substrate 512, a first dielectric stack 514 disposed over the first substrate 512, and a plurality of first interconnect structures 516 surrounded by the first dielectric stack 514. The first substrate 512 may be or include a bulk semiconductor, a semiconductor-on-insulator (SOI) substrate, or the like, and may be doped (e.g., with a p-type or an n-type dopant) or undoped. Various semiconductor devices may be on or in the first substrate 512. For example, the semiconductor devices may include FETs, diodes, capacitors, inductors, and other devices. The semiconductor device may be formed completely within the first substrate 512, partially in the first substrate 512 and partially in the first dielectric stack 514, or completely in the first dielectric stack 514, for example. The first interconnect structures 516 over the first substrate 512 are electrically coupled to the semiconductor devices to form an integrated circuit. The integrated circuit can be any circuit, such as an application specific integrated circuit (ASIC), a processor, a memory, or another circuit.

Referring to FIG. 4B, a second substrate 522 is provided and a conductive pillar 530 is formed in the second substrate 522 according to step 404 of FIG. 3. The conductive pillar 530 is formed in the second substrate 522 by etching the second substrate 522 to from a recess 524 in the second substrate 522 and depositing a conductive material in the recess 524. In some embodiments, a CMP operation is performed to remove an excess portion of the conductive material from an upper surface 523 of the second substrate 522. The conductive pillar 530 may be made of at least one material, such as Cu, Al, AlCu, AlSiCu, AlSi, Co, Ni, or the like.

After the formation of the conductive pillar 530, a lower interconnection dielectric 540 is deposited to fully cover the second substrate 522 and the conductive pillar 530, as shown in FIG. 4C. The lower interconnection dielectric 540 may, for example, comprise a low-k dielectric having a k-value less than about 4.0, such as about 2.0 or less. The lower interconnection dielectric 540 may be deposited using a CVD operation, a spin-coating operation, or another deposition technique. In some embodiments, a CMP operation or another planarization operation may be performed to planarize a top surface of the lower interconnection dielectric 540.

Next, a first etching operation is performed to remove portions of the lower interconnection dielectric 540 and form a plurality of openings 542 through the lower interconnection dielectric 540, wherein the conductive pillar 530 is exposed through one of the openings 542. The first etching operation can be a plasma-based etching process, such as an RIE process. After the forming of the openings 542, a conductive material is deposited in the openings 542 to form a first wiring layer 550 according to step 406 of FIG. 3. The first wiring layer 550 is electrically coupled to the conductive pillar 530. In some embodiments, the first wiring layer 550 may be formed of a material same as that used to form the conductive pillar 530. The first wiring layer 550 may be formed in a manner similar to that used to form the conductive pillar 530.

Referring to FIGS. 4D and 4E, an insulating film 500 is formed on one or more portions of the first wiring layer 550 according to step 408 of FIG. 3. In some embodiments, the insulating film 500 includes metal oxide material, such as tungsten oxide (WₓO_{y}), copper oxide (CuₓO_{y}), aluminum oxide (AlₓO_{y}), aluminum copper dioxide (AlₓCu_{y}O_{z}), Nickel oxide (NiₓO_{y}), etc; although other dielectric material may also be used.

In some embodiments, referring to FIG. 4D, the insulating film 500 is formed by oxidizing one or more portions of the first wiring layer 550, so that the insulating film 500 and the first wiring layer 550 can have a same material. In other words, the insulating film 500 and the first wiring layer 550 include a common element. The insulating film 500 includes an upper surface 5002 and a lower surface 5004 opposite to the upper surface. The lower surface 5004 of the insulating film 500 and an upper surface 541 of the lower interconnection dielectric 540 are at different vertical levels. In addition, the upper surface 5002 of the insulating film 500 and the upper surface 541 of the lower interconnection dielectric 540 are at different vertical levels. Referring to FIG. 4E, in an alternative step different from that shown in FIG. 4D, the insulating film 500 is formed by depositing a dielectric material on the lower interconnection dielectric 540 and the first wiring layer 550 and performing a patterning operation to remove a portion of the dielectric material covering the lower interconnection dielectric 540 and portions of the first wiring layer 550. The insulating film 500 in FIG. 4E includes an upper surface 5002 and a lower surface 5004 opposite to the upper surface, and the lower surface 5004 is flush with the upper surface of the lower interconnection dielectric 540.

Referring to FIG. 4F, a second dielectric stack 610 is formed on the lower interconnection dielectric 540, the first wiring layer 550, and the insulating film 500 according to step 410 of FIG. 3. For example, the second dielectric stack 610 may include two etch stop layers 612A and 612B interleaved with two isolation layers 614A and 614B. As shown in FIG. 4F, the etch stop layer 612A is in contact with the lower interconnection dielectric 540, the first wiring layer 550, and the insulating film 500. The etch stop layer 612A has a material different from that of the insulating film 500. In some embodiments, the etch stop layer 612A is a conformal layer covering the lower interconnection dielectric 540, the first wiring layer 550, and the insulating film 500.

The isolation layer 614A, the etch stop layer 612B, and the isolation layer 614B are sequentially disposed on the etch stop layer 612A. In some embodiments, the etch stop layers 612A and 612B may have a thickness T8, the isolation layer 614A may have a thickness T9 greater than the thickness T8, and the isolation layer 614B may have a thickness T10 greater than the thickness T9. For example, the thickness T9 of the isolation layer 614A and the thickness T10 of the isolation layer 614B are in a range from about 500 angstroms to about 100 k angstroms.

Referring to FIGS. 4G and 4H, a second interconnect structure 620 is formed in the second dielectric stack 610 according to step 412 of FIG. 3. The formation of the second interconnect structure 620 may include a dual damascene process, which includes forming one or more via-holes 616 in the second dielectric stack 610 and one or more trenches 618 in the isolation layer 614B, depositing a conductive material in the via-holes 616 and the trench 618, and then performing a planarization such as a CMP operation to cause a top surface of the conductive material to be level with a top surface of the isolation layer 614B.

Additional second dielectric stacks 610 and additional second interconnect structures 620 may be formed over the second substrate 522 for electrically coupling the semiconductor devices. Referring to FIG. 4I, five layers of the second interconnect structures 620 are shown over the second substrate 522, but an actual number of the second interconnect structures 620 is not limited thereto.

Subsequently, a patterned mask layer 700 is formed on portions of a topmost second dielectric stack 610 and a topmost second interconnect structure 620. The patterned mask layer 700 includes one or more openings 702 exposing one or more regions of a topmost isolation layer 614B. In some embodiments, the openings 702 may be disposed above the insulation film 500 or above the conductive pillar 530.

Referring to FIGS. 4J to 4L, a second etching operation is performed to form one or more through dielectric via-holes 640 through the second dielectric stacks 610 and the insulating film 500. In some embodiments, the second etching operation can include multiple sub-etching steps with different etching recipes to sequentially etch through the isolation layer 614B, the etch stop layer 612B, the isolation layer 614A, the etch stop layer 612A, and the insulating film 500.

Referring to FIG. 4J, one or more deep holes 630 are formed in the second dielectric stacks 610 according to step 414 of FIG. 3. In some embodiments, one or more portions of a bottommost etch stop layer 612A directly above the insulation film 500 and the conductive pillar 530 are exposed through the deep holes 630. Referring to FIG. 4K, portions of the bottommost etch stop layer 612A exposed through the deep holes 630 are removed to extend the deep holes 630 through the bottommost etch stop layer 612A, thereby exposing portions of the insulating film 500.

Referring to FIG. 4L, the insulating film 500 is etched to extend the deep holes 630 through and the insulating film 500 according to step 416 of FIG. 3. Accordingly, one or more through dielectric via-holes 640 are formed. In some embodiments, the through dielectric via-holes 640 have a depth D greater than a thickness T of the second interconnect structure 620. After the second etching operation, the patterned mask layer 700 is removed in an ashing and/or a wet strip operation, for example.

Referring to FIG. 4M, a conductive material is provided to fill the through dielectric via-holes 640 in according to step 418 of FIG. 3. In some embodiments, the conductive material is deposited and forms a through dielectric via 650 physically and electrically connected to the first wiring layer 550. In some embodiments, excess portions of the conductive material are removed to expose a top surface of the topmost isolation layer 614B. The excess portions of the conductive material may be removed by a CMP operation.

Referring to FIG. 4N, a semiconductor device 660 may be formed on the second dielectric stacks 610 and connected to the through dielectric via 650 and second interconnect structures 620. In some embodiments, the semiconductor device 660 may be a luminous device. The semiconductor device 660 may include, without limitation, light emitting elements, transmission elements, modulation elements, signal processing elements, switching circuits, amplifier, input/output coupler, and light sensing/detection circuits. Various processes are performed to form the semiconductor device 660, such as deposition, etching, implantation, photolithography, annealing, and/or other applicable processes.

Referring to FIG. 4O, the second substrate 522 is thinned to expose the conductive pillar 530 according to step 420 of FIG. 3. Accordingly, a second die 520 is completely formed. In some embodiments, the second substrate 522 is thinned to reduce a total thickness. The thinning of the second substrate 522 may be done by mechanical grinding, CMP, wet etching, atmospheric downstream plasma (ADP), dry chemical etching (DCE), a combination of aforementioned processes, or any another appropriate thinning method(s).

Referring to FIG. 4P, a bonding operation is performed to bond the second die 520 to the first die 510 according to step 422 of FIG. 3. Consequently, the integrated circuit device 50 is formed. After the bonding operation, the second substrate 522 is in contact with the first dielectric stack 514 and portions of the (topmost) first interconnect structures 516, and the through dielectric via 650 is connected to the (topmost) first interconnect structures 516.

In accordance with some embodiments of the present disclosure, a method of manufacturing an integrated circuit device includes: forming a semiconductor device on a substrate; forming a first interconnect structure over the semiconductor device and a dielectric layer to surrounded the first interconnect structure, wherein the first interconnect structure comprises a first conductive metal electrically coupled to the semiconductor device through a plurality of first vias; and forming a second interconnect structure over the first conductive metal, wherein the formation of the second interconnect structure includes: forming an insulating film over the first conductive metal; depositing an etch stop layer over the insulating film, wherein the etch stop layer and the insulating film include different materials; depositing a dielectric layer over the etch stop layer; performing a first etching operation to form a hole penetrating the dielectric layer to expose the etch stop layer; and causing the hole to extend through the etch stop layer and the insulating film and stop at the first conductive metal.

In accordance with some embodiments of the present disclosure, a method of manufacturing an integrated circuit device includes: providing a first die including a first substrate, a first interconnect structure over the first substrate, and a first dielectric layer to surrounded the first interconnect structure; providing a second die including a second substrate, a second interconnect structure over the second substrate, a second dielectric layer to surround the second interconnect structure; an insulating film on the second interconnect structure, an etch stop layer over the second dielectric layer and the insulating film, and an isolation layer over the etch stop layer; forming a hole penetrating through the isolation layer to expose the etch stop layer; causing the hole to extend through the etch stop layer and the insulating film; and depositing a conductive material in the hole to form a conductive via electrically coupled to the second interconnect structure.

In accordance with some embodiments of the present disclosure, an integrated circuit device includes a substrate including a plurality of semiconductor devices; an interconnect structure electrically coupled to the substrate and including a conductive metal electrically coupled to the substrate, an insulating film on the conductive metal, wherein the insulating film and the conductive metal comprise a common element, an etch stop layer over the insulating film, an isolation layer over the etch stop layer, and a conductive via penetrating the isolation layer, the etch stop layer and the insulating film and electrically coupled to the conductive metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an integrated circuit device, comprising:
forming a semiconductor device on a substrate;
forming a first interconnect structure over the semiconductor device and a dielectric layer to surround the first interconnect structure, wherein the first interconnect structure comprises a first conductive metal electrically coupled to the semiconductor device through a plurality of first vias; and
forming a second interconnect structure over the first conductive metal, wherein the formation of the second interconnect structure comprises:
forming an insulating film over the first conductive metal;
depositing an etch stop layer over the insulating film, wherein the etch stop layer and the insulating film include different materials;
depositing an isolation layer over the etch stop layer;
performing a first etching operation to form a hole penetrating through the isolation layer to expose the etch stop layer; and
causing the hole to extend through the etch stop layer and the insulating film and stop at the first conductive metal.

2. The method of claim 1, wherein the insulating film and the first conductive metal have a substantially same pattern.

3. The method of claim 1, wherein the formation of the insulating film comprises oxidizing the first conductive metal.

4. The method of claim 3, wherein a lower surface and an upper surface of the insulating film and an upper surface of the dielectric layer are at different vertical levels.

5. The method of claim 4, wherein the upper surface of the dielectric layer is between the lower surface of the insulating film and the upper surface of the insulating film in a cross-sectional view.

6. The method of claim 1, wherein a lower surface of the insulating film is flush with an upper surface of the dielectric layer when viewed in a cross-sectional view.

7. The method of claim 1, further comprising depositing a conductive material in the hole to form the second interconnect structure connected to the first interconnect structure.

8. The method of claim 1, wherein the first interconnect structure has a thickness less than a thickness of the second interconnect structure.

9. The method of claim 1, further comprising:
performing a second etching operation to form a trench in the isolation layer and connected to the hole, wherein a width of the trench is greater than a width of the hole;
and depositing a conductive material in the hole and the trench to form the second interconnect structure connected to the first interconnect structure.

10. The method of claim 9, wherein the trench has a first depth greater than a thickness of the first interconnect structure.

11. A method of manufacturing an integrated circuit device, comprising:
providing a first die, the first die comprising:
a first substrate;
a first interconnect structure over the first substrate; and
a first dielectric layer to surround the first interconnect structure;
providing a second die, the second die comprising:
a second substrate;
a second interconnect structure over the second substrate;
a second dielectric layer to surround the second interconnect structure;
an insulating film on the second interconnect structure;
an etch stop layer over the second dielectric layer and the insulating film; and
an isolation layer over the etch stop layer;
forming a hole penetrating through the isolation layer to expose the etch stop layer;
causing the hole to extend through the etch stop layer and the insulating film; and
depositing a conductive material in the hole to form a conductive via electrically coupled to the second interconnect structure.

12. The method of claim 11, wherein formation of the insulating film comprises oxidizing the second interconnect structure.

13. The method of claim 12, wherein a lower surface and an upper surface of the insulating film and an upper surface of the second dielectric layer are at different vertical levels.

14. The method of claim 11, wherein a lower surface of the insulating film is flush with an upper surface of the second dielectric layer when viewed in a cross-sectional view.

15. The method of claim 11, wherein the hole has a depth greater than a thickness of the second interconnect structure.

16. The method of claim 11, further comprising:
bonding the first die to the second die,
wherein the second die further includes a conductive pillar electrically coupled to the second interconnect structure and disposed under the insulating film, and the conductive pillar is physically connected to a topmost first interconnect structure after the first die and the second die are bonded.

17. The method of claim 11, further comprising:
bonding the first die to the second die,
wherein after the first die and the second die are bonded, the second substrate is in contact with the first dielectric layer and portions of the first interconnect structure.

18. An integrated circuit device, comprising:
a substrate comprising a plurality of semiconductor devices;
an interconnect structure electrically coupled to the substrate and comprising:
a conductive metal electrically coupled to the substrate;
an insulating film on the conductive metal, wherein the insulating film and the conductive metal comprise a common element;
an etch stop layer over the insulating film;
an isolation layer over the etch stop layer; and
a conductive via penetrating the isolation layer, the etch stop layer and the insulating film and electrically coupled to the conductive metal.

19. The integrated circuit device of claim 18, wherein the insulating film and the conductive metal have a substantially same pattern.

20. The integrated circuit device of claim 18, wherein the conductive metal has a thickness less than a thickness of the conductive via.
